(19) United States
(12) Patent Application Publication
(10) Pub. No.: US 2026/0186061 A1
(43) Pub. Date: Jul. 2, 2026

(54) Apparatus and Method for Diagnosing Battery State

(71) Applicant: LG Energy Solution, Ltd., Seoul (KR)

(72) Inventors: Juyoung Kang, Daejeon (KR); Heungil Park, Daejeon (KR); Jungoh Seo, Daejeon (KR); Dajin Lee, Daejeon (KR); Inhwan Cho, Daejeon (KR)

(73) Assignee: LG Energy Solution, Ltd., Seoul (KR)

(21) Appl. No.: 19/127,471

(22) PCT Filed: Apr. 8, 2024
(86) PCT No.: PCT/KR2024/004596

§ 371 Date: May 6, 2025

(30) Foreign Application Priority Data
May 26, 2023 (KR) 10-2023-0068267
Apr. 5, 2024 (KR) 10-2024-0046605

(51) Int. Cl. G01R 31/3835; G01R 31/52; H01M 10/42

(52) U.S. Cl. CPC G01R 31/3835; G01R 31/52; H01M 10/4285

(57) ABSTRACT

Disclosed is a status diagnosis apparatus and method that may detect a cycle in which a first abnormal event occurs based on voltages of the battery when diagnosing an abnormality of a battery in progress of charging and discharging and determine the occurrence of a battery abnormality in an instance a second abnormal event occurs based on the OCV of the battery after the detected cycle, thereby providing improved safety and diagnostic reliability.

### CROSS-REFERENCE TO RELATED APPLICATIONS

The present application is a national phase entry of International Application No. PCT/KR2024/004596, filed on Apr. 8, 2024, and published as International Publication No. WO 2024/248309 A1, which claims priority from Korean Patent Application Nos. 10-2023-0068267, filed on May 26, 2023, and 10-2024-0046605, filed on Apr. 5, 2024, all of which are hereby incorporated herein by reference in their entireties.

### TECHNICAL FIELD

The present invention relates to an apparatus and method for diagnosing battery state, and more particularly, to an apparatus and method for diagnosing abnormal status of a battery state based on battery voltages and OCV pattern change during processing battery charge/discharge cycles.

### BACKGROUND

As depletion of fossil fuels proceeds and interest in environmental pollution increases, a demand for secondary batteries as an eco-friendly alternative energy source is rapidly increasing. Among various alternative energy sources, demand for rechargeable lithium secondary batteries is rapidly increasing.

Lithium secondary batteries are being applied to various industrial fields from mobile application devices to vehicles, robots and energy storage devices, as a response to environmental regulations and high oil price issues. However, lithium secondary batteries have a risk of ignition or explosion when an internal or external defect occurs, and thus, it is important to diagnose the condition of the battery in real time.

Accordingly, voltage and temperature used to be monitored to diagnose an abnormal state of the battery in the past.

However, the conventional battery state diagnosing method has a disadvantage that measurement values are prone to change due to surrounding environmental factors.

### SUMMARY OF THE INVENTION

### Technical Problem

To obviate one or more problems of the related art, embodiments of the present disclosure provide an apparatus for diagnosing battery state.

To obviate one or more problems of the related art, embodiments of the present disclosure also provide a method for diagnosing battery state.

### Technical Solution

In order to achieve the objective of the present disclosure, a battery status diagnosis apparatus may include at least one processor; and memory having programmed thereon instructions, wherein the instructions, when executed, cause the at least one processor to detect, from among a plurality of battery charge/discharge cycles, a cycle in which a first abnormal event occurs, wherein the first abnormal event is defined based on a battery voltage; detect, occurrence of a second abnormal event after the cycle in which the first abnormal event occurs, wherein the second abnormal event is defined based on an open circuit voltage (OCV) of the battery; and determine an abnormality of the battery based on occurrence of the second abnormal event.

The instructions may cause the at least one processor generate a virtual graph by connecting voltage values at a start time point and at an end time point of an inspection section of a given cycle among the battery charge/discharge cycles using virtual voltage values; and determine whether the first abnormal event occurs in the given cycle, based on one or more comparison values which are derived by individually calculating differences of measured voltage values within the inspection section of the cycle compared to the virtual voltage values on the virtual graph.

Here, the instructions may cause the at least one processor determine occurrence of the first abnormal event based on the one or more comparison values including both a positive value and a negative value.

According to an embodiment, the given cycle may be a charge cycle in which a magnitude of voltage decreases by a predefined threshold value or more.

According to another embodiment, the given cycle may be a discharge cycle in which a magnitude of voltage increases by a predefined threshold value or more.

Meanwhile, the detected cycle may be a charge cycle, and the second abnormal event may include a magnitude of charge OCV increasing by more than a predefined threshold within N cycles after the charge cycle.

In addition, the detected cycle may be a discharge cycle, and the second abnormal event may include a magnitude of charge OCV decreasing by more than a predefined threshold within N cycles after the discharge cycle.

Meanwhile, the instructions may cause the at least one processor to determine the abnormality of the battery to be occurrence of an open circuit in a battery electrode tab.

Furthermore, the instructions may cause the at least one processor to determine an open electrode tab in the battery to be short-circuited with another battery, based on the second abnormal event not occurring after a charge cycle in which the first abnormal event was detected.

Furthermore, the instructions may cause the at least one processor to determine an open electrode tab in the battery to be short-circuited with another battery, based on the second abnormal event not occurring after a discharge cycle in which the first abnormal event was detected.

According to another embodiment of the present disclosure, a method of diagnosing battery status by a battery status diagnosis apparatus may include detecting, from among a plurality of battery charge/discharge cycles, a cycle in which a first abnormal event occurs, wherein the first abnormal event is defined based on a battery voltage; detecting occurrence of a second abnormal event after the cycle in which the first abnormal event occurs, wherein the second abnormal event is defined based on an open circuit voltage (OCV) of the battery; and determining an abnormality of the battery based on occurrence of the second abnormal event.

Here, the detecting the cycle in which the first abnormal event occurs may include: generating a virtual graph by connecting voltage values at a start time point and at an end time point of an inspection section of a given cycle among the battery charge/discharge cycles using virtual voltage values; and determining whether the first abnormal event occurs in the given cycle, based on one or more comparison values which are derived by individually calculating differences of measured voltage values within the inspection section of the cycle compared to the virtual voltage values on the virtual graph.

Here, determining occurrence of the first abnormal event may be based on the one or more comparison values including both a positive value and a negative value.

According to an embodiment, the given cycle may be a charge cycle in which a magnitude of voltage decreases by a predefined threshold value or more.

According to another embodiment, the given cycle may be a discharge cycle in which a magnitude of voltage increases by a predefined threshold value or more.

Meanwhile, the detected cycle may be a charge cycle, and the second abnormal event may include a magnitude of charge OCV increasing by more than a predefined threshold within N cycles after the charge cycle.

Furthermore, the detected cycle may be a discharge cycle, and the second abnormal event may include a magnitude of charge OCV decreasing by more than a predefined threshold within N cycles after the discharge cycle.

Meanwhile, the method may further include determining the abnormality of the battery to be occurrence of an open circuit in a battery electrode tab.

Furthermore, the method may further include: determining an open electrode tab in the battery to be short-circuited with another battery, based on the second abnormal event not occurring after a charge cycle in which the first abnormal event was detected.

Furthermore, the method may further include: determining an open electrode tab in the battery to be short-circuited with another battery, based on the second abnormal event not occurring after a discharge cycle in which the first abnormal event was detected.

### Advantageous Effects

The battery status diagnosis apparatus and method according to the embodiments and experimental examples of the present invention may determine occurrence of abnormality of the battery based on the battery voltage and open-circuit voltage (OCV) pattern change when diagnosing abnormality of the battery performing charge/discharge, thereby enhancing safety and diagnostic reliability.

### BRIEF DESCRIPTION OF THE DRAWINGS

FIG. 1 is a block diagram of a battery system to which embodiments of the present invention may be applied.

FIG. 2 is an example image of a battery tab that is open.

FIG. 3 is a block diagram of a battery status diagnosis apparatus according to embodiments of the present invention.

FIG. 4 is a flowchart for explaining a method for diagnosing a battery status according to embodiments of the present invention.

FIG. 5 flowchart illustrating a method of detecting a specific cycle in which a first abnormal event occurs in the battery status diagnosis method according to embodiments of the present invention.

FIG. 6 is a graph showing charge/discharge voltage measurements of a battery according to an experimental example of the present invention.

FIG. 7 is an enlarged graph of area A of FIG. 6.

FIG. 8 is a graph of battery voltage in the inspection section within a charge cycle in which an event is detected according to a first experimental example of the present invention.

FIG. 9 is a table showing comparison data per time within the inspection section according to FIG. 8.

FIG. 10 is a voltage graph of the battery in the inspection section within a discharge cycle where an event is detected according to a second experimental example of the present invention.

FIG. 11 is a table showing comparison data per time within the inspection section according to FIG. 10.

FIG. 12 is a table summarizing OCV measurement values for each charge/discharge cycle of the battery according to a third experimental example of the present invention.

FIG. 13 is an enlarged graph of area B of FIG. 6.

FIG. 14 is a graph showing the OCV measurement values for each charge/discharge cycle of the battery according to a third experimental example of the present invention.

1000: battery status diagnosis apparatus
100: memory
200: processor
300: transceiver
400: input interface
500: output interface
600: storage device
700: bus

### DETAILED DESCRIPTION

The present invention may be modified in various forms and have various embodiments, and specific embodiments thereof are shown by way of example in the drawings and will be described in detail below. It should be understood, however, that there is no intent to limit the present invention to the specific embodiments, but on the contrary, the present invention is to cover all modifications, equivalents, and alternatives falling within the spirit and technical scope of the present invention. Like reference numerals refer to like elements throughout the description of the figures.

It will be understood that, although the terms such as first, second, A, B, and the like may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes combinations of a plurality of associated listed items or any of the plurality of associated listed items.

It will be understood that when an element is referred to as being “coupled” or “connected” to another element, it can be directly coupled or connected to the other element or an intervening element may be present. In contrast, when an element is referred to as being “directly coupled” or “directly connected” to another element, there is no intervening element present.

The terms used herein is for the purpose of describing specific embodiments only and are not intended to limit the present invention. As used herein, the singular forms “a”, “an” and “the” are intended to include the plural forms as well, unless the context clearly indicates otherwise. It will be further understood that the terms “comprises”, “comprising”, “includes”, “including” and/or “having”, when used herein, specify the presence of stated features, integers, steps, operations, constitutional elements, components and/or combinations thereof, but do not preclude the presence or addition of one or more other features, integers, steps, operations, constitutional elements, components, and/or combinations thereof.

Unless otherwise defined, all terms used herein, including technical and scientific terms, have the same meanings as commonly understood by one skilled in the art to which the present invention belongs. It will be further understood that terms, such as those defined in commonly used dictionaries, should be interpreted as having meanings that are consistent with their meanings in the context of the relevant art and will not be interpreted in an idealized or overly formal sense unless expressly so defined herein.

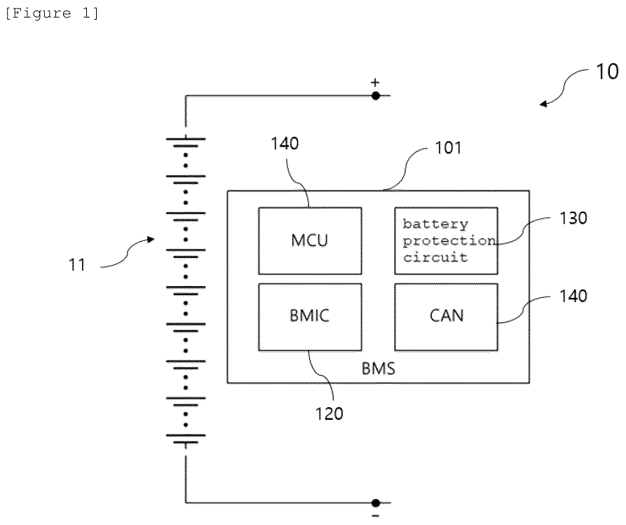

FIG. 1 is a block diagram of a battery system to which embodiments of the present invention may be applied.

Referring to FIG. 1, a battery pack 10 or battery module may include a plurality of battery cells 11 connected in series. The battery pack or module may be connected to a load through a positive terminal 12 and a negative terminal 13 to perform charging or discharging. The most commonly used battery cell is a lithium-ion (Li-Ion) battery cell.

A battery management system (BMS) 101 may be connected to a battery module 10 or battery pack.

The battery management system 101 may monitor a current, a voltage and a temperature of each battery cell 11 or module to be managed, calculate state of charge (SOC) of the battery based on monitoring results to control charging and discharging. Here, the state of Charge (SOC) refers to a current state of charge of a battery, represented in percent points [%], and the State of Health (SOH) may be a current condition of a battery compared to its ideal conditions, represented in percent points [%].

The BMS 101 may monitor battery cells 11, read cell voltages, and transmit them to other systems connected to the battery.

Furthermore, the battery management system 101 monitors at least one electrical component constituting the battery system and passes their status data on to other systems. For this, the BMS 101 includes a communication module for communicating with other systems in a device including the battery system.

The communication module of the BMS can communicate with other systems in the device using CAN (Controller Area Network) 140. Here, components, modules or systems in the BMS are connected to each other through a CAN bus. Accordingly, the battery management system (BMS) 101 may use CAN communication to remotely transmit status data obtained through monitoring of the battery pack or module and at least one electrical component constituting the battery management system (BMS) to other systems.

Meanwhile, the battery management system (BMS) 101 may equally balance charges of the battery cells in order to extend the life of the battery system.

The BMS 100 may include various components such as a fuse, a current sensing element, a thermistor, a switch, and a balancer to perform such operations. In most cases, a micro controller unit (MCU) 110 or a battery monitoring integrated chip (BMIC) 120 for interworking and controlling these components is additionally included in the BMS 101. Here, the BMIC 120 may be located inside the battery management system (BMS) 101 and may be an IC-type component that measures information such as voltage, temperature, and current of a battery cell/module. According to an embodiment, a battery management system (BMS) may be applied to an automobile.

Meanwhile, generally, a battery management system (BMS) 101 may be connected with a battery protection device 130 which blocks the charging and discharging circuit when a battery abnormality occurs. In other words, a general battery protection circuit 130 blocks the charging and discharging circuit when an abnormality occurs in any one battery cell or module so as to limit the use of the battery.

The battery status diagnosis apparatus according to embodiments of the present invention may be implemented by being included in a battery management system (BMS).

Hereinafter, preferred embodiments according to the present invention will be described in more detail with reference to the attached drawings.

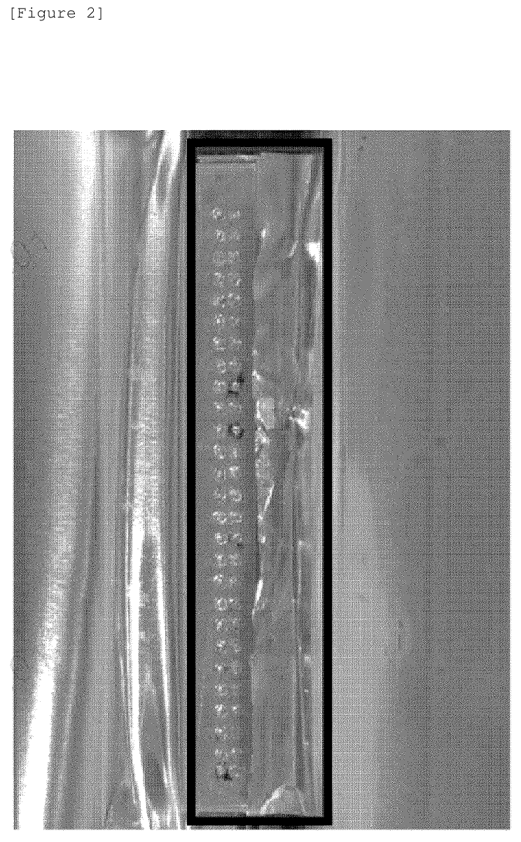

FIG. 2 is an example image of a battery tab that is open.

Referring to FIG. 2, the battery status diagnosis apparatus may be a device that pre-diagnoses an abnormal state of a battery in order to prevent battery ignition. To be more specific, the battery status diagnosis apparatus can diagnose disconnection of an electrode tab located inside a battery to prevent ignition due to battery disconnection.

According to embodiments, the battery status diagnosis apparatus may monitor voltage measured during charging and discharging of a battery and detect a cycle in which a first abnormal event occurs.

Thereafter, the battery status diagnosis apparatus may monitor a pattern of open circuit voltage (OCV) in subsequent cycles based on the detected cycle and determine an abnormal state of the battery according to whether a predefined second abnormal event occurs or not.

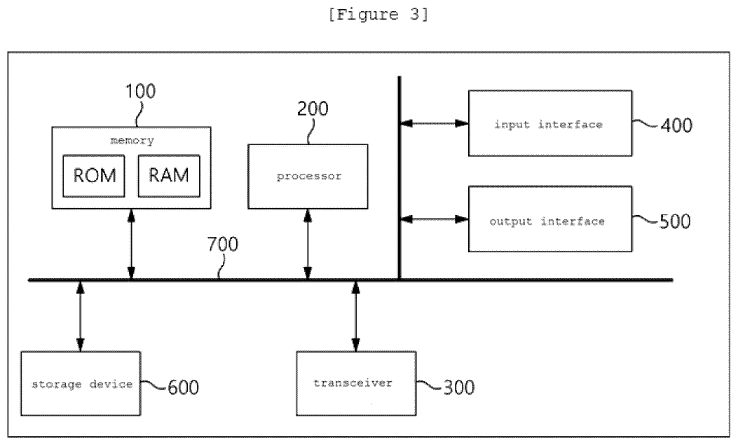

FIG. 3 is a block diagram of a battery status diagnosis apparatus according to embodiments of the present invention.

Referring to FIG. 3, the battery status diagnosis apparatus 1000 may include a memory 100, a processor 200, a transceiver 300, an input interface 400, an output interface 500, and a storage device 600.

According to embodiments, respective components 100, 200, 300, 400, 500, 600 included in the battery status diagnosis apparatus 1000 may be connected by a bus 700 to communicate with each other.

The memory 100 and the storage device 600 among the components 100, 200, 300, 400, 500, 600 may include at least one of a volatile storage medium and a non-volatile storage medium. For example, the memory 100 and the storage device 600 may include at least one of read only memory (ROM) and random access memory (RAM).

Among them, the memory 100 may include at least one instruction executed by the processor 200.

According to embodiments, the at least one instruction may include an instruction to detect a cycle in which a first abnormal event occurs during battery charge/discharge cycles are performed, wherein the first abnormal event is defined based on a battery voltage; and an instruction to determine that an abnormality has occurred in the battery when a second abnormal event occurs after the cycle in which the first abnormal event occurs, wherein the second abnormal event is defined based on an open circuit voltage (OCV) of the battery.

The instruction to detect the cycle in which the first abnormal event occurs may include: an instruction to generate a virtual graph by connecting voltage values at the start time point and at the end time point of an inspection section of a specific cycle among battery charge/discharge cycles; and an instruction to determine whether the first abnormal event occurs in the cycle, based on one or more comparison values which are derived by individually calculating differences of voltage values over time within the inspection section of the cycle compared to virtual voltage values on the virtual graph.

Here, the instruction to determine whether the first abnormal event has occurred in the cycle may include an instruction to determine that a first abnormal event has occurred when the one or more comparison values include a positive number and a negative number.

According to an embodiment, the specific cycle may include at least one charge cycle which includes an event in which a magnitude of voltage is decreased by a predefined threshold value or more among charge cycles of the battery.

According to another embodiment, the specific cycle may include at least one discharge cycle which includes an event in which a magnitude of voltage increases by more than or equal to a predefined threshold among discharge cycles of the battery.

Meanwhile, the second abnormal event may include, upon the detected cycle being a charge cycle, an event in which a magnitude of charge OCV within N cycles after the charge cycle increases beyond a predefined threshold.

In addition, the second abnormal event may include, upon the detected cycle being a discharge cycle, an event in which a magnitude of charge OCV within N cycles after the discharge cycle decreases beyond a predefined threshold.

Meanwhile, the instruction to determine that an abnormality has occurred in the battery may include an instruction to determine that an open circuit has occurred in a battery electrode tab.

Furthermore, the at least one instruction may further include an instruction to determine that an open electrode tab in the battery is short-circuited with another battery, if the second abnormal event does not occur after a charge cycle in which the first abnormal event was detected.

Furthermore, the at least one instruction may further include an instruction to determine that an open electrode tab in the battery is short-circuited with another battery, if the second abnormal event does not occur after a discharge cycle in which the first abnormal event was detected.

Meanwhile, the processor 200 may mean a central processing unit (CPU), a graphics processing unit (GPU), or a dedicated processor on which methods according to embodiments of the present invention are performed.

The processor 200 may execute at least one program command stored in the memory 100 as described above.

The battery status diagnosis apparatus according to embodiments of the present invention has been described above. Hereinafter, a battery status diagnosing method performed by process operations of the battery status diagnosis apparatus will be described.

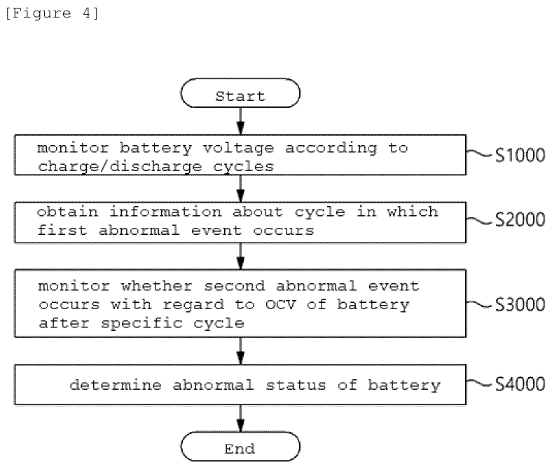

FIG. 4 is a flowchart for explaining a method for diagnosing a battery status according to embodiments of the present invention.

Referring to FIG. 4, the battery diagnosis apparatus 1000 may monitor the voltage pattern of the battery measured while charge/discharge cycles are being performed (S1000). Here, the battery voltage may be measured by the battery status diagnosis apparatus 1000 or received from an external device in real time.

Thereafter, the battery status diagnosis apparatus 1000 may detect a specific cycle in which a first abnormal event occurs when monitoring the battery voltage (S2000). Here, the first abnormal event will be described in more detail when explaining a diagnosing method of the battery status diagnosis apparatus.

Thereafter, the battery status diagnosis apparatus 1000 may monitor open circuit voltages (OCV) in subsequent cycles following after the obtained specific cycle. According to embodiments, the battery status diagnosis apparatus 1000 may monitor whether a second abnormal event as to the open circuit voltage occurs within one or more predefined cycles performed after the specific cycle (S3000). Here, the open-circuit voltage (OCV) may be a voltage value of the battery measured in an open state where no load is applied to the battery, which means when the battery is in a rest time. In addition, as described above, the second abnormal event may be an abnormal event that is predefined with regard to the open-circuit voltage (OCV) while a battery charge/discharge cycle progresses.

Thereafter, the battery status diagnosis apparatus 1000 may determine an abnormal status of the battery based on whether the second abnormal event occurs (S4000).

According to one embodiment, when the battery is in progress of charge cycles, the battery status diagnosis apparatus 1000 may monitor charge OCV values within N cycles (predefined cycles) after a specific charge cycle in which the first abnormal event occurs. Here, when the charge OCV values satisfy the second abnormal event, which means that the charge OCV values are increased by a threshold or more and maintained, wherein the threshold is predefined based on the charge OCV value in the specific charge cycle, the battery status diagnosis apparatus 1000 may determine that an abnormality has occurred in the battery. For example, to explain in more detail, the battery status diagnosis apparatus 1000 may determine that a disconnection has occurred in an electrode tab located inside the battery when the charge OCV values within one or more predefined cycles are increased by a predefined threshold or more and maintained, after the charge cycle in which the first abnormal event occurred.

According to another embodiment, when the battery is performing discharge cycles, the battery status diagnosis apparatus 1000 may check discharge OCV values within N cycles following after a specific discharge cycle in which the first abnormal event occurs. Here, when the discharge OCV values satisfy the second abnormal event, which means when the discharge OCV values are reduced by a threshold or more and maintained, wherein the threshold is predefined based on the discharge OCV value in the specific discharge cycle, the battery status diagnosis apparatus 1000 may determine that an abnormality has occurred in the battery. For example, to explain in more detail, the battery status diagnosis apparatus 1000 may determine that a disconnection has occurred in an electrode tab located inside the battery when the discharge OCV values within a predefined cycles, after the discharge cycle in which the first abnormal event occurs, are decreased by more than or equal to a predefined threshold value and remains.

Meanwhile, to be described in more detail according to another embodiment, the battery status diagnosis apparatus 1000 may determine that an abnormality has occurred in the battery even when there is no change beyond a predefined threshold in the discharge OCV values or in the charge OCV values within predefined cycles based on the charge or discharge cycle in which the first abnormal event occurs. For example, the battery status diagnosis apparatus 1000 may determine that an electrode tab of the battery is open and short-circuited with another adjacent battery when a second abnormal event in the charge OCV values or the discharge OCV values does not occur within each predefined cycle, based on a specific charge cycle or a specific discharge cycle in which the first abnormal event occurs.

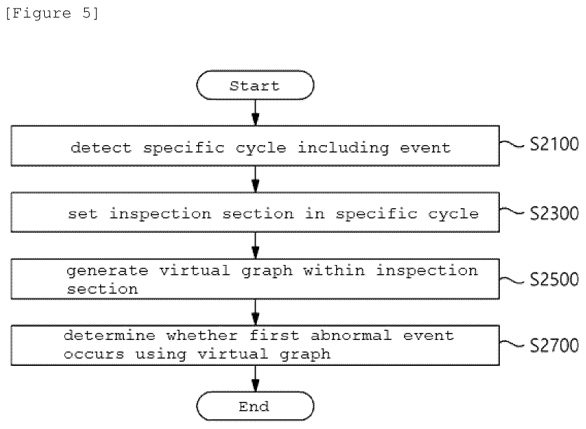

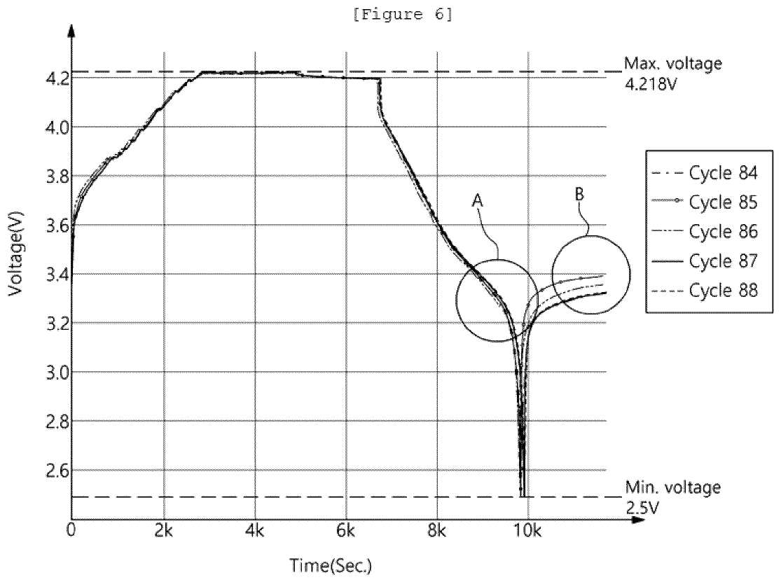

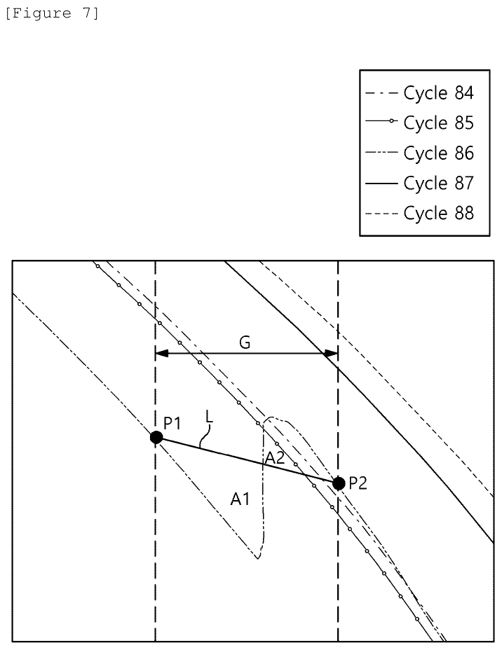

FIG. 5 is a flowchart illustrating a method of detecting a specific cycle in which a first abnormal event occurs in the battery status diagnosis method according to embodiments of the present invention, FIG. 6 is a graph showing charge/discharge voltage measurements of a battery according to an experimental example of the present invention, and FIG. 7 is an enlarged graph of area A of FIG. 6.

Referring to FIGS. 5 to 7, the battery status diagnosis apparatus 1000 may monitor charge/discharge cycles of the battery. Accordingly, the battery status diagnosis apparatus 1000 may detect a specific cycle including an event in which a magnitude of voltage deviates by more than a predefined threshold (S2100).

According to one embodiment, when the battery is in a process of a charge cycle, the battery status diagnosis apparatus 1000 may detect a specific cycle including an event in which the magnitude of the voltage is reduced by more than or equal to a predefined threshold.

According to another embodiment, when the battery is undergoing a discharge cycle, the battery status diagnosis apparatus 1000 may detect a specific cycle including an event in which the magnitude of the voltage is increased by more than a predefined threshold. Here, the magnitude of the predefined threshold may be adjusted by a manager.

Thereafter, the battery status diagnosis apparatus 1000 may check whether the event in the specific cycle is a first abnormal event.

In more detail, the battery status diagnosis apparatus 1000 may set an inspection section G including the event, based on the event (S2300).

According to one embodiment, the inspection section G may be set to include a predefined period of time based on the time when the event occurs. For example, the predefined period of time is 50 seconds and the inspection section (G) may be set to a total of 100 seconds including 50 seconds before and after the time when the event occurs.

According to another embodiment, the inspection section G may be set at a predefined constant time interval from the start of the charge/discharge cycle of the battery, regardless of when the event occurs.

Thereafter, the battery status diagnosis apparatus 1000 may generate a virtual graph (L) within the inspection section (G) (S2500). Here, the virtual graph (L) may be a straight-line graph connecting the voltage data (P1) at the start of the inspection section (G) of the specific cycle and the voltage data (P2) at the end point of the inspection section (G) of the specific cycle, based on the specific cycle in which the event was detected. Here, the specific cycle may be a charge cycle or a discharge cycle including the event according to charging and discharging of the battery.

Thereafter, the battery status diagnosis apparatus 1000 may determine whether the first abnormal event occurs in the specific cycle using the virtual graph L (S2700).

To be more specific, the battery status diagnosis apparatus 1000 may calculate comparison data by comparing virtual values located on the virtual graph L and voltage values in the specific cycle at each time point. In other words, the comparison data per time may be data obtained by subtracting voltage data of the specific cycle from the virtual data at the same time point. Thereafter, the battery status diagnosis apparatus 1000 may determine whether a first abnormal event has occurred based on the calculated comparison data. For example, the battery status diagnosis apparatus 1000 may determine that the first abnormal event has occurred when the comparison data in the inspection section G includes both positive and negative values.

According to one embodiment, when the specific cycle is a charge cycle, the comparison data may include values sequentially ranging from positive to negative.

According to another embodiment, when the specific cycle is a discharge cycle, the comparison data may include values sequentially ranging from a negative value (A1) to a positive value (A2), as shown in FIG. 7.

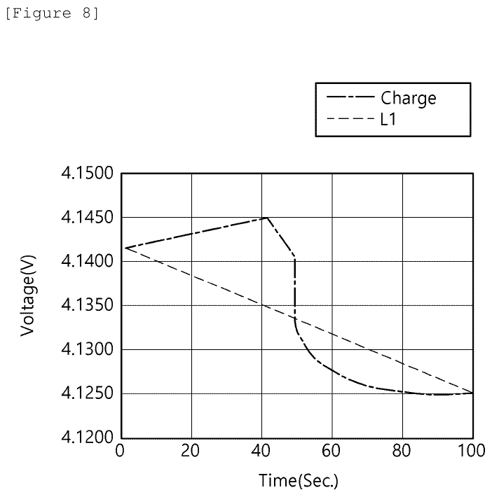

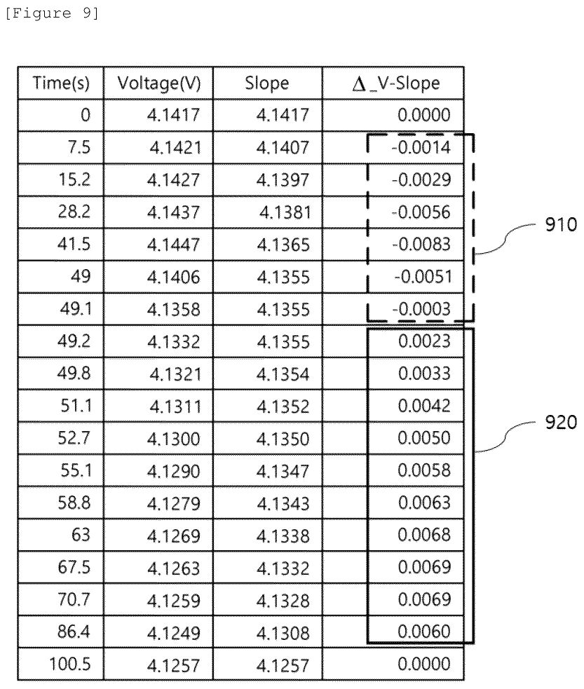

FIG. 8 is a graph of battery voltage in the inspection section within a charge cycle in which an event is detected according to a first experimental example of the present invention and FIG. 9 is a table showing comparison data per time within the inspection section according to FIG. 8.

Referring to FIGS. 8 and 9, the battery status diagnosis apparatus 1000 according to the first experimental example of the present invention, when charging the battery, detects a charge cycle including an event in which voltage change more than a predefined threshold value occurs. Afterwards, the battery status diagnosis apparatus 1000 sets an inspection section (G) for the charge cycle and determines whether the first abnormal event occurs in the charge cycle. In other words, the battery status diagnosis apparatus 1000 may apply an inspection section (G) at 100-s intervals to the charge cycle in which the event occurred to determine whether the first abnormal event occurs in the inspection section (G).

To be more specific, the battery status diagnosis apparatus 1000 creates a virtual graph (L1) which is a straight-line graph connecting a point of 4.1417V that is the voltage (P1) at the start of the inspection section (G) and a point of 4.1257V that is the voltage (P2) at the end of the inspection section (G), wherein the point of 4.1417 V and the point of 4.1257V are selected among the charge voltage data from 0 to 100 seconds of the inspection section (G).

Thereafter, the battery status diagnosis apparatus 1000 compares the difference between the charge voltage data within the inspection section G (Voltage (V)) and the virtual graph L1 (Slope). As a result of the comparison (Δ_V-Slope), as shown in FIG. 9, it is understood that the comparison data 910 in the charge cycle of the battery has negative values from 0 second to 49.1 seconds and the data 920 from 49.2 seconds to less than 100 seconds has positive values. Accordingly, the battery status diagnosis apparatus 1000 may determine that the comparison data in the corresponding inspection section G includes both negative and positive values and that a first abnormal event has occurred.

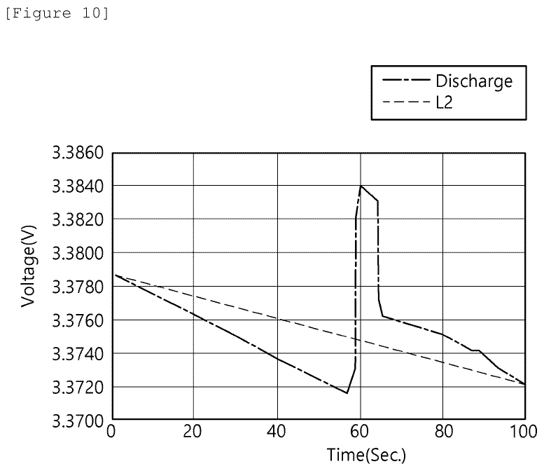

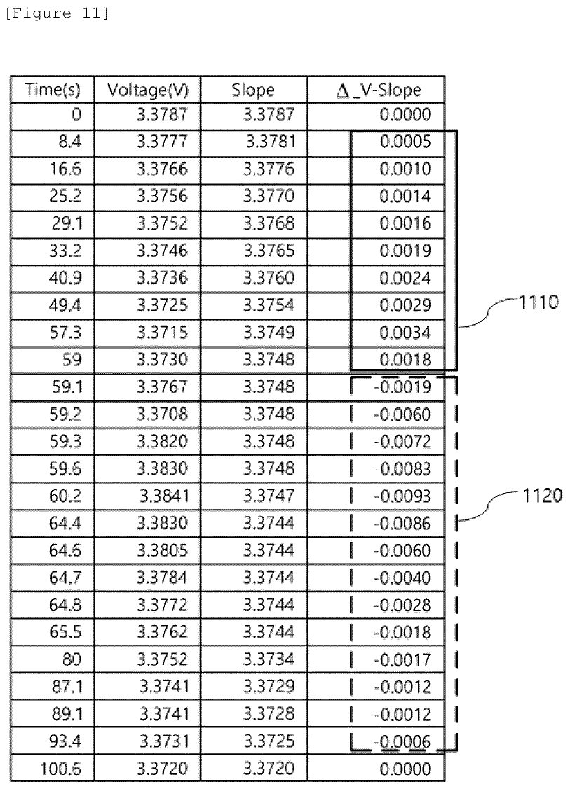

FIG. 10 is a voltage graph of the battery in the inspection section within a discharge cycle where an event is detected according to a second experimental example of the present invention and FIG. 11 is a table showing comparison data per time within the inspection section according to FIG. 10.

Referring to FIGS. 10 and 11, the battery status diagnosis apparatus 1000 according to the second experimental example of the present invention, when charging the battery, detects a discharge cycle including an event in which voltage change more than or equal to a predefined threshold value occurs. Afterwards, the battery status diagnosis apparatus 1000 sets an inspection section (G) for the discharge cycle and determines whether the first abnormal event occurred in the discharge cycle. In other words, the battery status diagnosis apparatus 1000 may apply an inspection section (G) at 100-s intervals to the discharge cycle in which the event occurred to determine whether the first abnormal event occurs in the inspection section (G).

To be more specific, as shown in FIG. 10, the battery status diagnosis apparatus 1000 creates a virtual graph (L2), which is a straight-line graph including a point of 3.3787V that is the voltage (P1) at the start of the inspection section (G) and a point of 3.3720V that is the voltage (P2) at the end of the inspection section (G), wherein the point of 3.3787V and the point of 3.3720V are selected among the discharge voltage data from 0 to 100 seconds of the inspection section (G).

Thereafter, the battery status diagnosis apparatus 1000 compares the difference between the discharge voltage data (Voltage (V)) within the inspection section G and the virtual graph L2 (Slope).

As a result of the comparison (Δ_V-Slope), as shown in FIG. 11, it is understood that the comparison data 1110 in the discharge cycle of the battery has positive values from 0 second to 59 seconds and the comparison data 1120 has negative values from 59.1 seconds to 100 seconds. Accordingly, the battery status diagnosis apparatus 1000 may determine that the comparison data in the corresponding inspection section G includes both negative and positive values and that a first abnormal event has occurred.

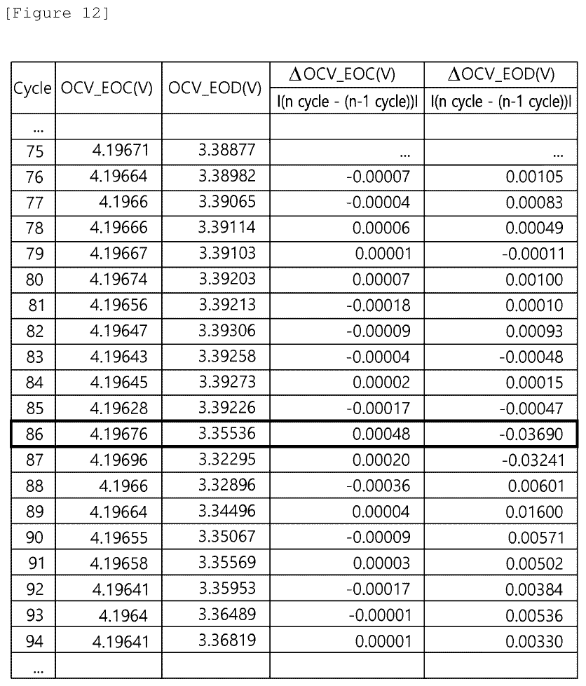

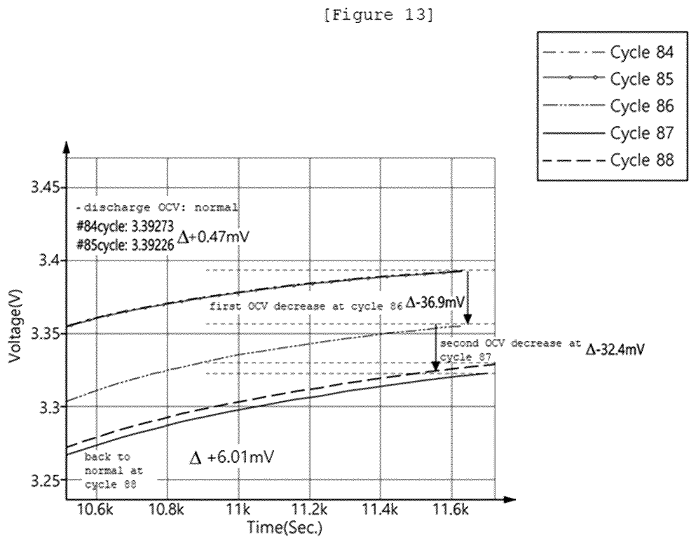

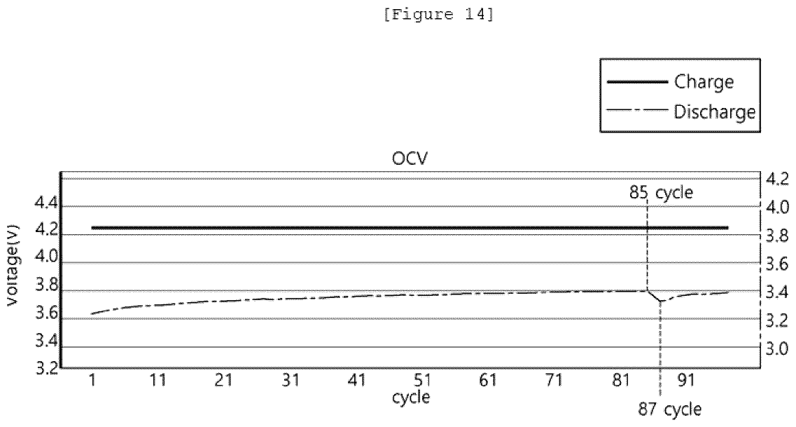

FIG. 12 is a table summarizing OCV measurement values for each charge/discharge cycle of the battery according to a third experimental example of the present invention, FIG. 13 is an enlarged graph of area B of FIG. 6, and FIG. 14 is a graph showing the OCV measurement values for each charge/discharge cycle of the battery according to a third experimental example of the present invention.

Referring to FIGS. 12 and 13, the battery status diagnosis apparatus 1000 may monitor the amount of change in charge OCV (ΔOCV_EOC) and amount of change in discharge OCV (ΔOCV_EOD) within a threshold cycle which is subsequent to the cycle in which the first abnormal event occurred.

According to an experimental example, the battery status diagnosis apparatus 1000 monitors the discharge OCV change amount (ΔOCV_EOD) from cycle 86 which is the cycle in which the first abnormal event occurred, to cycle 87 which is the predefined cycle.

As a result of checking discharge OCVs in previous cycles before the first abnormal event occurred based on the 86th cycle using the battery status diagnosis apparatus 1000, the discharge OCV was 3.39273V at the 84th cycle and 3.39226V at the 85th cycle, in which the discharge OCV difference is Δ0.47 mV that is not substantially high.

Meanwhile, at cycle 86 which the first abnormal event occurred, the discharge OCV is measured at 3.35536V, which shows a significant decrease by −36.9 mV compared to cycle 85. In addition, at cycle 87 which is the predefined cycle, the discharge OCV was measured at 3.32295V, which shows a significant decrease by −32.4 mV compared to cycle 86.

In other words, it can be understood that in the 86th cycle and the 87th cycle, which correspond to the predefined cycle based on the specific cycle, the discharge OCV has decreased by more than Δ0.30 mV, which is a predefined threshold, compared to its previous cycle, the 85th cycle or the 86th cycle, respectively. Accordingly, the battery status diagnosis apparatus 1000 may determine that a disconnection has occurred in an electrode tab within the battery.

Thereafter, as a result of continuously monitoring discharge OCVs of the battery after cycle 87 using the battery status diagnosis apparatus 1000, the discharge OCV of the battery is measured to be 3.32896V at cycle 88, which is higher than the previous cycle, cycle 87, which shows increases in the discharge OCV by 46.01 mV. However, as shown in FIG. 14, the size of the discharge OCV after cycle 87 does not recover to the size of the discharge OCV during the 85th cycle of normal operation, which means that a disconnection has occurred in the electrode tab in the battery.

The battery status diagnosis apparatus and method according to the embodiments and experimental examples of the present invention have been described above.

The battery status diagnosis apparatus and method according to embodiments and experimental examples of the present invention may monitor voltage pattern according to the charge/discharge cycles of the battery to detect the cycle in which a first abnormal event occurs and determine that a disconnection occurs in an electrode tab of the battery when a second abnormal event occurs in an open-circuit voltage value in one or more subsequent cycles based on the detected cycle, and the thus, abnormal status of the battery can be diagnosed based on the battery voltage and open-circuit voltage value, thereby ensuring safe use of the battery.

The operations of the method according to the embodiments of the present invention may be implemented as a computer-readable program or code on a computer-readable recording medium. The computer-readable recording medium includes all types of recording devices in which data readable by a computer system is stored. In addition, the computer-readable recording medium may be distributed in a network-connected computer system to store and execute computer-readable programs or codes in a distributed manner.

In addition, the computer-readable recording medium may include hardware devices specially configured to store and execute program instructions, such as ROM, RAM, flash memory, etc. The program instructions may include not only machine language code created by a compiler, but also high-level language code that can be executed by a computer using an interpreter.

Although some aspects of the invention have been described in the context of the apparatus, it may also represent a description according to a corresponding method, wherein a block or apparatus corresponds to a method step or feature of a method step. Similarly, aspects described in the context of a method may also represent a feature of a corresponding block or item or a corresponding apparatus. Some or all of the method steps may be performed by (or using) a hardware device, such as, for example, a microprocessor, a programmable computer, or an electronic circuit. In some embodiments, one or more of the most important method steps may be performed by such an apparatus.

In the forgoing, the present invention has been described with reference to the exemplary embodiment of the present invention, but those skilled in the art may appreciate that the present invention may be variously corrected and changed within the range without departing from the spirit and the area of the present invention described in the appending claims.

1. A battery status diagnosis apparatus comprising:
at least one processor; and
memory having programmed thereon instructions, wherein the instructions, when executed, cause the at least one processor to:
detect, from among a plurality of battery charge/discharge cycles, a cycle in which a first abnormal event occurs, wherein the first abnormal event is defined based on a battery voltage;
detect, occurrence of a second abnormal event after the cycle in which the first abnormal event occurs, wherein the second abnormal event is defined based on an open circuit voltage (OCV) of the battery; and
determine an abnormality of the battery based on occurrence of the second abnormal event.

2. The apparatus of claim 1, wherein the instructions cause the at least one processor to
generate a virtual graph by connecting voltage values at a start time point and at an end time point of an inspection section of a given cycle among the battery charge/discharge cycles using virtual voltage values; and
determine whether the first abnormal event occurs in the given cycle, based on one or more comparison values which are derived by individually calculating differences of measured voltage values within the inspection section of the cycle compared to the virtual voltage values on the virtual graph.

3. The apparatus of claim 2, wherein the instructions cause the at least one processor to determine occurrence of the first abnormal event based on the one or more comparison values including both a positive value and a negative value.

4. The apparatus of claim 2, wherein the given cycle is a charge cycle in which a magnitude of voltage decreases by a predefined threshold value or more.

5. The apparatus of claim 2, wherein the given cycle is a discharge cycle in which a magnitude of voltage increases by a predefined threshold value or more.

6. The apparatus of claim 1, wherein the detected cycle is a charge cycle, and wherein the second abnormal event includes a magnitude of charge OCV increasing by more than a predefined threshold within N cycles after the charge cycle.

7. The apparatus of claim 1, wherein the detected cycle is a discharge cycle, and wherein the second abnormal event includes a magnitude of charge OCV decreasing by more than a predefined threshold within N cycles after the discharge cycle.

8. The apparatus of claim 1, wherein the instructions cause the at least one processor to determine the abnormality of the battery to be occurrence of an open circuit in a battery electrode tab.

9. The apparatus of claim 1, wherein the instructions cause the at least one processor to determine an open electrode tab in the battery to be short-circuited with another battery, based on the second abnormal event not occurring after a charge cycle in which the first abnormal event was detected.

10. The apparatus of claim 1, wherein the instructions cause the at least one processor to determine an open electrode tab in the battery to be short-circuited with another battery, based on the second abnormal event not occurring after a discharge cycle in which the first abnormal event was detected.

11. A method of diagnosing battery status by a battery status diagnosis apparatus, the method comprising:
detecting, from among a plurality of battery charge/discharge cycles, a cycle in which a first abnormal event occurs, wherein the first abnormal event is defined based on a battery voltage;
detecting occurrence of a second abnormal event after the cycle in which the first abnormal event occurs, wherein the second abnormal event is defined based on an open circuit voltage (OCV) of the battery; and
determining an abnormality of the battery based on occurrence of the second abnormal event.

12. The method of claim 11, wherein the detecting the cycle in which the first abnormal event occurs includes:
generating a virtual graph by connecting voltage values at a start time point and at an end time point of an inspection section of a given cycle among the battery charge/discharge cycles using virtual voltage values; and
determining whether the first abnormal event occurs in the given cycle, based on one or more comparison values which are derived by individually calculating differences of measured voltage values within the inspection section of the cycle compared to the virtual voltage values on the virtual graph.

13. The method of claim 12, wherein determining occurrence of the first abnormal event is based on the one or more comparison values including both a positive value and a negative value.

14. The method of claim 12, wherein the given cycle is a charge cycle in which a magnitude of voltage decreases by a predefined threshold value or more.

15. The method of claim 12, wherein the given cycle is a discharge cycle in which a magnitude of voltage increases by a predefined threshold value or more.

16. The method of claim 11, wherein the detected cycle is a charge cycle, and wherein the second abnormal event includes a magnitude of charge OCV increasing by more than a predefined threshold within N cycles after the charge cycle.

17. The method of claim 12, wherein the detected cycle is a discharge cycle, and wherein the second abnormal event includes a magnitude of charge OCV decreasing by more than a predefined threshold within N cycles after the discharge cycle.

18. The method of claim 11, further comprising determining the abnormality of the battery to be occurrence of an open circuit in a battery electrode tab.

19. The method of claim 11, further comprising:
determining an open electrode tab in the battery to be short-circuited with another battery, based on the second abnormal event not occurring after a charge cycle in which the first abnormal event was detected.

20. The method of claim 11, further comprising:
determining an open electrode tab in the battery to be short-circuited with another battery, based on the second abnormal event not occurring after a discharge cycle in which the first abnormal event was detected.
